(19) United States
(12) Patent Application Publication
(10) Pub. No.: US 2026/0251868 A1
(43) Pub. Date: Aug. 27, 2026

(54) ELECTRONIC DEVICE

(71) Applicant: InnoLux Corporation, Miao-Li County (TW)

(72) Inventors: Jui-Jen YUEH, Miao-Li County (TW); Wen-Bin HUNG, Miao-Li County (TW); Tsung-Han TSAI, Miao-Li County (TW); Kuan-Feng LEE, Miao-Li County (TW)

(21) Appl. No.: 19/457,715

(22) Filed: Jan. 23, 2026

(30) Foreign Application Priority Data
Feb. 25, 2025 (CN) 202510209612.X

(51) Int. Cl. G02B 6/42; H10W 90/00; H10W 90/10

(52) U.S. Cl. CPC G02B 6/4259; G02B 6/4239; H10W 90/10; H10W 90/401

(57) ABSTRACT

An electronic device includes: a first substrate including a cavity having a first bottom surface; a photonic die disposed in the cavity and having a second bottom surface facing the first bottom surface; a connection element disposed between the first bottom surface and the second bottom surface; and a first waveguide disposed corresponding to the photonic die and configured to receive an optical signal from the photonic die, wherein a roughness of the first bottom surface of the first substrate is different from a roughness of the second bottom surface of the photonic die.

### CROSS-REFERENCE TO RELATED APPLICATIONS

This application claims the benefits of the Chinese Patent Application Serial Number 202510209612.X, filed on February 25, 2025, the subject matter of which is incorporated herein by reference.

### BACKGROUND

### Field

The present disclosure relates to an electronic device and, more specifically to an electronic device with a photonic die and/or a waveguide.

### Description of Related Art

In recent years, with the continuous development of science and technology, technologies such as artificial intelligence and cloud computing, which require high-density and high-performance chips, have grown rapidly. The high density and high performance of chips not only test the manufacturer's process technology, but are also prone to causing electronic devices to overheat.

Traditional electronic devices that rely solely on electrical signals for transmission are increasingly unable to meet market demand. Optical signals offer advantages over electrical signals, including greater bandwidth, faster transmission rates, lower power consumption, and improved anti-interference capabilities. Therefore, how to integrate components that can transmit optical signals with electronic devices is still a direction that requires continued research.

Therefore, it is desirable to provide an electronic device in order to meet market demand.

### SUMMARY

The present disclosure provides an electronic device, comprising: a first substrate comprising a cavity, wherein the cavity has a first bottom surface; a photonic die disposed in the cavity and having a second bottom surface facing the first bottom surface; a connection element disposed between the first bottom surface and the second bottom surface; and a first waveguide disposed corresponding to the photonic die and configured to receive an optical signal from the photonic die, wherein a roughness of the first bottom surface of the first substrate is different from a roughness of the second bottom surface of the photonic die.

The present disclosure further provides another electronic device, comprising: a second substrate comprising a first through hole and a first side surface surrounding the first through hole; an insulating layer disposed on the second substrate and comprising a second through hole and a second side surface surrounding the second through hole, wherein the first through hole and the second through hole are overlapped in a top view direction of the electronic device; an active layer disposed on the insulating layer and comprising a third waveguide and a photoelectric converter optically coupled to the third waveguide; a semiconductor die disposed on the active layer and electrically connected to the photoelectric converter; and a conductive unit electrically connected to the semiconductor die and comprising a first portion and a second portion, wherein the first portion is disposed in the first through hole, and the second portion is disposed in the second through hole, wherein a roughness of the first side surface of the second substrate is different from a roughness of the second side surface of the insulating layer.

The present disclosure further provides another electronic device, comprising: a first substrate comprising a cavity; a photonic die disposed in the cavity of the first substrate; a first waveguide disposed corresponding to the photonic die and receiving an optical signal from the photonic die; a second substrate disposed on the first substrate; a semiconductor die disposed on the second substrate; and a third waveguide disposed between the second substrate and the semiconductor die and receiving the optical signal through the first waveguide.

Other novel features of the disclosure will become more apparent from the following detailed description when taken in conjunction with the accompanying drawings.

### BRIEF DESCRIPTION OF DRAWINGS

FIG. 1A is a cross-sectional schematic view of a part of an electronic device according to one embodiment of the present disclosure.

FIG. 1B is a cross-sectional schematic view of the line A-A’ in FIG. 1A.

FIG. 2A is a cross-sectional schematic view of a part of an electronic device according to another embodiment of the present disclosure.

FIG. 2B is a partial enlarged view of FIG. 2A.

FIG. 3 is a cross-sectional schematic view of a part of an electronic device according to another embodiment of the present disclosure.

FIG. 4A is a cross-sectional schematic view of a part of a first waveguide according to one embodiment of the present disclosure.

FIG. 4B is a top view of a part of a third waveguide according to one embodiment of the present disclosure.

FIG. 4C is a cross-sectional schematic view of the line B-B’ in FIG. 4A.

FIG. 4D is a cross-sectional schematic view of the line C-C’ in FIG. 4B.

FIG. 5 is a cross-sectional schematic view of a part of an electronic device according to another embodiment of the present disclosure.

FIG. 6A and FIG. 6B respectively are cross-sectional schematic views of the line D-D’ in FIG. 5 according to different embodiments.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as "first", "second" and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as "comprising", "including", "containing", and "having" are open-ended words, so they should be interpreted as meaning "containing but not limited to...". Therefore, when the terms "comprising", "including", "containing" and/or "having" are used in the description of the present disclosure, they specify the existence of corresponding features, regions, steps, operations and/or components, but do not exclude the existence of one or more corresponding features, regions, steps, operations and/or components.

The terms, such as "about", "substantially", or "approximately", are generally interpreted as within 10%, 5%, 3%, 2%, 1%, or 0.5% of a given value or range. The quantity given here is an approximate quantity, that is, without specifying "about", "approximately", "substantially" and "approximately", "about", "approximately", "substantially" and "approximately" can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as "below" or "under" and "on", "above" or "over" may be used in the embodiments to describe the relative relationship between one element and another element in the drawings. It will be understood that if the device in the drawing was turned upside down, elements described on the "lower" side would then become elements described on the "upper" side. When a unit (for example, a layer or a region) is referred to as being "on" another unit, it can be directly on the another unit or there may be other units therebetween. Furthermore, when a unit is said to be "directly on another unit", there is no unit therebetween. Moreover, when a unit is said to be "on another unit", the two have a top-down relationship in a top view, and the unit can be disposed above or below the another unit, and the top-bottom relationship depends on the orientation of the device.

In the present disclosure, any two values or directions used for comparison may have a certain error. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

In the present disclosure, the thickness, the length, the width, or the distance and angle between elements may be measured by using an optical microscope (OM), scanning electron microscope (SEM), film thickness profiler (α-step), ellipsometer, or other suitable methods. More specifically, according to some embodiments, a scanning electron microscope can be used to obtain a cross-sectional image of the structure and measure the thickness, length, width of each element or the distance and angle between elements. In addition, the roughness of the structure can be obtained by using a scanning electron microscope to obtain a cross-sectional image of the structure and obtain the arithmetic average roughness (Ra) or the ten-point average roughness (Rz).

It should be noted that the technical solutions provided in the following different embodiments can be replaced, combined or mixed with each other to form another embodiment without violating the spirit of the present disclosure.

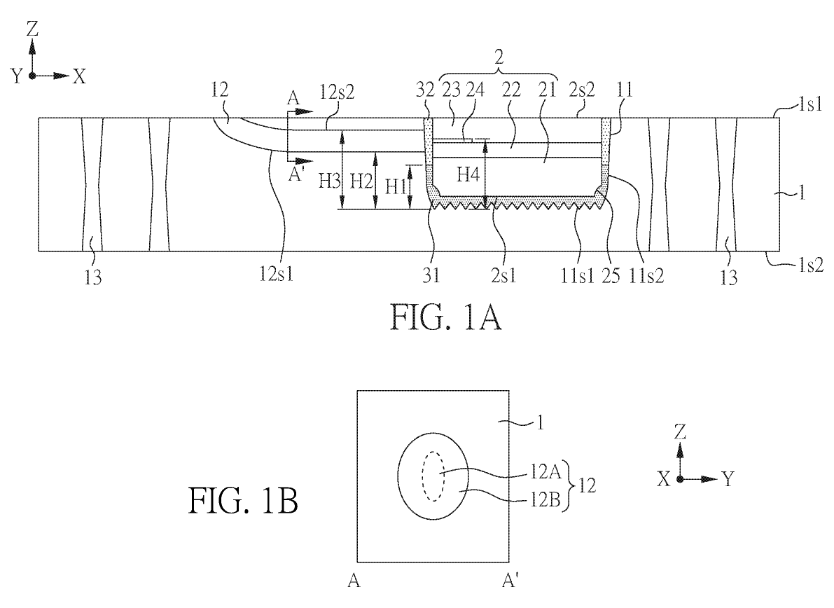

FIG. 1A is a cross-sectional schematic view of a part of an electronic device according to one embodiment of the present disclosure. FIG. 1B is a cross-sectional schematic view of the line A-A’ in FIG. 1A.

In one embodiment of the present disclosure, as shown in FIG. 1A, the electronic device may comprise: a first substrate 1 comprising a cavity 11, wherein the cavity 11 has a first bottom surface 11s1; a photonic die 2 disposed in the cavity 11 and having a second bottom surface 2s1 facing the first bottom surface 11s1; a connection element 31 disposed between the first bottom surface 11s1 and the second bottom surface 2s1; and a first waveguide 12 disposed corresponding to the photonic die 2 and receiving an optical signal from the photonic die 2.

More specifically, as shown in FIG. 1A, the first substrate 1 comprises an upper surface 1s1 and a lower surface 1s2 opposite to the upper surface 1s1. The cavity 11 is formed by a concavity of the upper surface 1s1 of the first substrate 1, that is, the cavity 11 is formed by the first bottom surface 11s1 and a side wall 11s2 connecting the first bottom surface 11s1 and the upper surface 1s1 of the first substrate 1. The photonic die 2 has a second bottom surface 2s1 and a top surface 2s2 opposite to the second bottom surface 2s1. When the photonic die 2 is disposed in the cavity 11 of the first substrate 1, the top surface 2s2 of the photonic die 2 may be approximately co-planar with the upper surface 1s1 of the first substrate 1. The photonic die 2 may be fixed in the cavity 11 of the first substrate 1 through the connection element 31, so the optical signal provided by the photonic die 2 can be stably transmitted to the first waveguide 12. In the present disclosure, the roughness of the first bottom surface 11s1 of the cavity 11 of the first substrate 1 may be different from the roughness of the second bottom surface 2s1 of the photonic die 2. For example, the roughness of the first bottom surface 11s1 of the cavity 11 of the first substrate 1 may be greater than the roughness of the second bottom surface 2s1 of the photonic die 2. Thus, the contact area between the connection element 31 and the first bottom surface 11s1 may be increased, thereby improving the fixing effect of the photonic die 2. In one embodiment of the present disclosure, the cavity 11 is a concavity structure not penetrating the first substrate 1 and defined by the side wall of the first substrate 1.

In one embodiment of the present disclosure, as shown in FIG. 1A, the first substrate 1 may selectively comprise a plurality of through holes 13 if it is needed, and a conductive material may be selectively disposed in the through holes 13, but the present disclosure is not limited thereto. In the present disclosure, the material of the first substrate 1 may comprise glass, silicon, silicon carbide, ceramic, resin, other suitable materials or a combination thereof, but the present disclosure is not limited thereto. In one embodiment of the present disclosure, the first substrate 1 may be a glass substrate. In the present disclosure, the material of the first waveguide 12 may comprise glass, silicon, plastic, other suitable material or a combination thereof, but the present disclosure is not limited thereto. In the present disclosure, the refractive index of the first waveguide 12 may be greater than the refractive index of the first substrate 1. In the present disclosure, the material of the connection element 31 comprises an adhesive material, such as acrylic, epoxy resin, other suitable materials or a combination thereof, but the present disclosure is not limited thereto. In one embodiment of the present disclosure, the first waveguide 12 is used as a medium that transmits optical signals.

In the present disclosure, the “photonic die 2” refers to a die comprising photonic integrated circuit (PIC). For example, as shown in FIG. 1A, the photonic die 2 may comprise a base layer 21; a circuit layer 23 disposed on the base layer 21; an insulating layer 22 disposed between the base layer 21 and the circuit layer 23; and a second waveguide 24 disposed on the insulating layer 22 and used to transmit the optical signal to the first waveguide 12. That is, in the present disclosure, the optical signal provided by the photonic die 2 may transmit to the first waveguide 12 through the second waveguide 24. The structure of the photonic die 2 shown in FIG. 1A is exemplary and can be adjusted as needed. Even not shown in the figure, the photonic die 2 may further comprise other components. In one embodiment of the present disclosure, as shown in FIG. 1A, in one cross section, the photonic die 2 may comprise a chamfer structure 25, which may reduce defects caused by collision between the photonic die 2 and the cavity 11, thereby improving the reliability of the photonic die 2. The “chamfer structure” refers to, for example, the non-right or non-sharp corners or curved corners of the photonic die 2 in the cross-section. In the present disclosure, the material of the base layer 21 may comprise silicon, silicon carbide (SiC), gallium nitride (GaN), gallium arsenide (GaAs), silicon germanium (SiGe), diamond, quartz, ceramic, glass, but the present disclosure is not limited thereto. In the present disclosure, the material of the insulating layer 22 may comprise silicon oxide, silicon nitride, silicon oxynitride, other suitable materials or a combination thereof, but the present disclosure is not limited thereto. In the present disclosure, the circuit layer 23 may comprise conductor lines, pads, drive circuits, other suitable components, or a combination thereof. Suitable components may comprise passive components, active components, or a combination thereof, such as capacitors, resistors, inductors, diodes, transistors, etc., but the present disclosure is not limited thereto. In the present disclosure, the material of the second waveguide 24 may comprise glass, silicon, plastics, other suitable material or a combination thereof, but the present disclosure is not limited thereto. In one embodiment of the present disclosure, the second waveguide 24 is used as a medium that transmits optical signals.

In one embodiment of the present disclosure, as shown in FIG. 1A, the electronic device may further comprise an optical layer 32 disposed between the first waveguide 12 and the second waveguide 24. In the present disclosure, the optical layer 32 is prepared by a material with high transmittance for optical signals, thereby reducing the impact of the optical layer 32 on the optical signals. Suitable materials comprise a transparent organic material, such as polycarbonate (PC), polyimide (PI), polyethylene terephthalate (PET), polyether polyol (POP), polymethylmethacrylate (PMMA), cycloolefin polymer (COP), rubber, ultraviolet light curing adhesive (UV adhesive), optical clear adhesive (OCA), optical clear resin (OCR), acrylic resin, other suitable material or a combination thereof, but the present disclosure is not limited thereto. In one embodiment of the present disclosure, the optical layer 32 may optionally have adhesive properties, thereby strengthening the fixation of the photonic die 2 in the cavity 11. The “high transmittance” refers to, for example, the transmittance for the optical signals being greater than 70%, greater than 80% or greater than 90%, but the present disclosure is not limited thereto. In one embodiment of the present disclosure, the transmittance of the optical layer 32 for the optical signals may be greater than or equal to the transmittance of the connection element 31 for the optical signals. In one embodiment of the present disclosure, the adhesive of the optical layer 32 may be less than or equal to the adhesive of the connection element 31.

In one embodiment of the present disclosure, as shown in FIG. 1A, in a cross sectional view, the first waveguide 12 has a side 12s1 adjacent to the lower surface 1s2 of the first substrate 1 and another side 12s2 away from the lower surface 1s2 of the first substrate 1. That is, the side 12s1 of the first waveguide 12 is closer to the lower surface 1s2 of the first substrate 1 compared to the side 12s2. The height from the connection element 31 to the first bottom surface 11s1 of the cavity 11 may be a first height H1; the height from the side 12s1 of the first waveguide 12 to the first bottom surface 11s1 of the cavity 11 may be a second height H2; the height from the side 12s2 of the first waveguide 12 to the first bottom surface 11s1 of the cavity 11 may be a third height H3; and the height from the second waveguide 24 to the first bottom surface 11s1 of the cavity 11 may be a fourth height H4. The first height H1 is less than the second height H2, the second height H2 is less than the fourth height H4, and the fourth height H4 is less than the third height H3. The “first height H1” refers to, for example, in a cross-sectional view, a distance between the top surface of the connection element 31 and the first bottom surface 11s1 of the cavity 11 in the normal direction Z of the first substrate 1. The “fourth height H4” refers to, for example, in a cross-sectional view, the distance between the top surface of the second waveguide 24 and the first bottom surface 11s1 of the cavity 11 in the normal direction Z of the first substrate 1.

In one embodiment of the present disclosure, the second height H2, the third height H3 and the fourth height H4 may satisfy the following equation:

[H2+(H3-H2)/4] ≤ H4 ≤ [H3-(H3-H2)/4]

wherein, H2 is the second height, H3 is the third height and H4 is the fourth height.

In one embodiment of the present disclosure, as shown in FIG. 1A, the first waveguide 12 may be embedded into the first substrate 1. The first waveguide 12 may be formed by modifying a specific area inside the first substrate 1 by irradiating laser light. Thus, as shown in FIG. 1B, a cross section of the first waveguide 12 may be, for example, oval (or circular) and comprises a first portion 12A and a second portion 12B surrounding the first portion 12A, wherein the refractive index of the first portion 12A is greater than the refractive index of the second portion 12B. In another embodiment of the present disclosure, the first waveguide 12 may be disposed on the first substrate 1, but the present disclosure is not limited thereto.

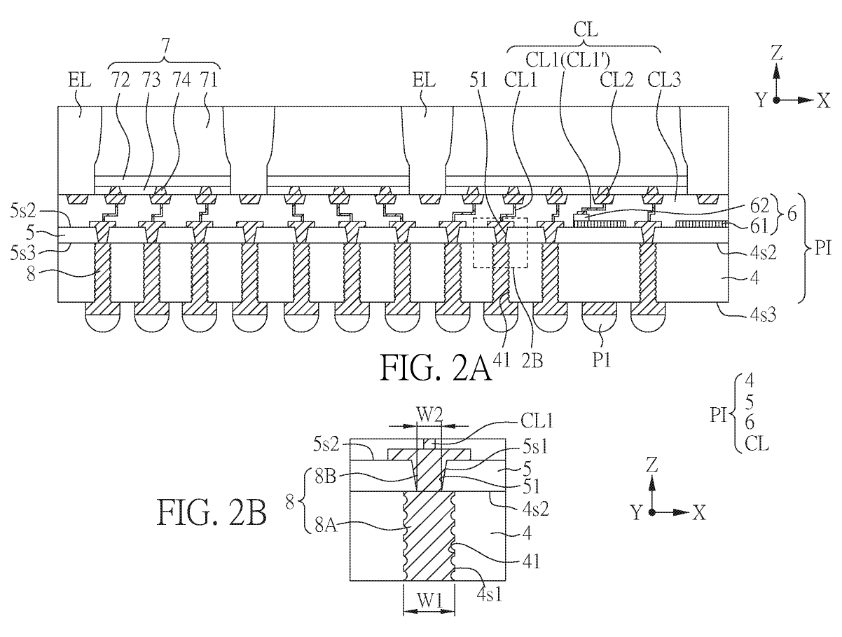

FIG. 2A is a cross-sectional schematic view of a part of an electronic device according to another embodiment of the present disclosure. FIG. 2B is a partial enlarged view of FIG. 2A.

In one embodiment of the present disclosure, as shown in FIGS. 2A and 2B, the electronic device may comprise: a second substrate 4 comprising a first through hole 41 and a first side surface 4s1 surrounding the first through hole 41; an insulating layer 5 disposed on the second substrate 4 and comprising a second through hole 51 and a second side surface 5s1 surrounding the second through hole 51, wherein, in a top view direction of the electronic device (for example, in the normal direction Z of the second substrate 4), the first through hole 41 and the second through hole 51 are overlapped; an active layer 6 disposed on the insulating layer 5 and comprising a third waveguide 61 and a photoelectric converter 62 optically coupled to the third waveguide 61; a semiconductor die 7 disposed on the active layer 6 and electrically connected to the photoelectric converter 62; and a conductive unit 8 electrically connected to the semiconductor die 7 and comprising a first portion 8A and a second portion 8B, wherein the first portion 8A is disposed in the first through hole 41, and the second portion 8B is disposed in the second through hole 51.

More specifically, as shown in FIGS. 2A and 2B, the second substrate 4 comprises an upper surface 4s2 and a lower surface 4s3 opposite to the upper surface 4s2. The insulating layer 5 is disposed between the second substrate 4 and the active layer 6, and for example, the insulating layer 5 may respectively contact the second substrate 4 and the active layer 6. The insulating layer 5 comprises an upper surface 5s2 and a lower surface 5s3 opposite to the upper surface 5s2. The first through hole 41 penetrates the second substrate 4, the second through hole 51 penetrates the insulating layer 5, and the first through hole 41 and the second through hole 51 are connected to each other. The semiconductor die 7 may comprise: a base layer 71; an interconnection layer 72; a dielectric layer 73, wherein the interconnection layer 72 is disposed between the base layer 71 and the dielectric layer 73; and a plurality of connection pads 74 disposed in the dielectric layer 73. The first portion 8A of the conductive unit 8 is disposed in the first through hole 41, the second portion 8B of the conductive unit 8 is disposed in the second through hole 51, and the first portion 8A and the second portion 8B are connected to each other. The first portion 8A of the conductive unit 8 may extend and be disposed on the lower surface 4s3 of the second substrate 4 and be electrically connected to a pad P1, and the second portion 8B of the conductive unit 8 may extend and be disposed on the upper surface 5s2 of the insulating layer 5.

In one embodiment of the present disclosure, as shown in FIG. 2A, the electronic device may further comprise a circuit layer CL disposed between the semiconductor die 7 and the conductive unit 8, wherein the semiconductor die 7 is electrically connected to the conductive unit 8 through the circuit layer CL. More specifically, the circuit layer CL may comprise a plurality of conductive elements CL1 disposed on the conductive unit 8; a plurality of connection pads CL2 disposed on the plurality of conductive elements CL1 and electrically connected to the plurality of conductive elements CL1; and a dielectric layer CL3, wherein the conductive element CL1 and the connection pad CL2 are disposed in the dielectric layer CL3. In the present disclosure, the connection pad CL2 of the circuit layer CL is electrically connected to the connection pad 74 of the semiconductor die 7, and at least one of the conductive elements CL1 of the circuit layer CL is electrically connected to the conductive unit 8, thereby transmitting the electrical signals between the semiconductor die 7 and the pad P1 through the circuit layer CL and the conductive unit 8. Another one of the conductive elements CL1 of the circuit layer CL (for example, the conductive element CL1’) may be electrically connected to the photoelectric converter 62 and the semiconductor die 7 respectively, and the optical signal and/or electrical signal is converted by the photoelectric converter 62 and transmitted between the semiconductor die 7 and the third waveguide 61. More specifically, for example, the photoelectric converter 62 may converted the optical signal provided by the third waveguide 61 into electrical signal, and transmit to the semiconductor die 7 through another conductive element CL1 (for example, the conductive element CL1’) and the connection pad CL2. Or, the electrical signal provided by the semiconductor die 7 may transmit to the photoelectric converter 62 through the connection pad CL2 and another conductive element CL1 (for example, the conductive element CL1’), and the photoelectric converter 62 converts the electrical signal into optical signal and transmits to the third waveguide 61. In the present disclosure, the second substrate 4, the insulating layer 5, the active layer 6 and the circuit layer CL may form a photonic interposer PI, wherein the semiconductor die 7 is disposed on the photonic interposer PI.

In one embodiment of the present disclosure, as shown in FIGS. 2A and 2B, the roughness of the first side surface 4s1 of the second substrate 4 is different from the roughness of the second side surface 5s1 of the insulating layer 5. For example, the roughness of the first side surface 4s1 of the second substrate 4 is greater than the roughness of the second side surface 5s1 of the insulating layer 5. The roughness of the side surface affects component adhesion and/or signal transmission efficiency. Increasing the roughness of the side surface can improve component adhesion, while reducing the roughness of the side surface can improve signal transmission efficiency. Thus, when the roughness of the first side surface 4s1 and the roughness of the second side surface 5s1 meets the aforesaid requirement, the adhesion and/or signal transmission efficiency of the conductive unit 8 can be improved.

In one embodiment of the present disclosure, as shown in FIGS. 2A and 2B, in a cross section, the width W2 of the second through hole 51 of the insulating layer 5 is less than the width W1 of the first through hole 41 of the second substrate 4. The “width of the through hole” refers to, for example, in a cross section, the maximum dimension measured at the interface between the insulating layer 5 and the second substrate 4. In one embodiment of the present disclosure, as shown in FIG. 2A, in the top view direction of the electronic device (for example, in the normal direction Z of the second substrate 4), the third waveguide 61 and the second through hole 51 are not overlapped. In one embodiment of the present disclosure, as shown in FIG. 2A, in the top view direction of the electronic device (for example, in the normal direction Z of the second substrate 4), the third waveguide 61 and the first through hole 41 are not overlapped.

In one embodiment of the present disclosure, as shown in FIG. 2A, the electronic device may comprise a plurality of semiconductor dies 7, the semiconductor dies 7 may be insulated from each other through an encapsulation layer EL, and each semiconductor die 7 is electrically connected to the conductive unit 8 corresponding thereto through the circuit layer CL respectively.

In the present disclosure, the material of the second substrate 4 may comprise glass, silicon, silicon carbide, ceramic, resin, other suitable materials or a combination thereof, but the present disclosure is not limited thereto. In one embodiment of the present disclosure, the second substrate 4 may be a silicon substrate. In the present disclosure, the material of the insulating layer 5 and the encapsulation layer EL may respectively comprise silicon oxide, silicon nitride, silicon oxynitride, other suitable materials or a combination thereof, but the present disclosure is not limited thereto. In the present disclosure, the material of the third waveguide 61 may comprise silicon, silicon carbide (SiC), gallium nitride (GaN), gallium arsenide (GaAs), silicon germanium (SiGe), diamond, quartz, ceramic, glass, plastic, other suitable materials or a combination thereof, but the present disclosure is not limited thereto. In the present disclosure, the photoelectric converter 62 comprises a component that can perform photoelectric conversion. In the present disclosure, the material of the base layer 71 may be referred to above, which is not described again here. In the present disclosure, the interconnection layer 72 may comprise a conductive line, a pad, a drive circuit, other suitable components or a combination thereof. Suitable components may comprise passive components, active components, or a combination thereof, such as capacitors, resistors, inductors, diodes, transistors, etc., but the present disclosure is not limited thereto. In the present disclosure, the material of the dielectric layer 73 and the dielectric layer CL3 may respectively comprise silicon oxide, silicon nitride, silicon oxynitride, other suitable materials or a combination thereof, but the present disclosure is not limited thereto. In the present disclosure, the semiconductor die 7 may comprise a system-on-chip (SoC), a central processing unit (CPU), a graphics processing unit (GPU), a memory, a logic die or a combination thereof, but the present disclosure is not limited thereto. In the present disclosure, the materials of the connection pad 74, the conductive unit 8, the conductive element CL1 and the connection pad CL2 may respectively comprise a metal, a metal oxide, an alloy thereof or a combination thereof, such as gold, silver, copper, palladium, platinum, ruthenium, aluminum, cobalt, nickel, titanium, molybdenum, manganese, indium zinc oxide (IZO), indium tin oxide (ITO), indium tin zinc oxide (ITZO), indium gallium zinc oxide (IGZO), or aluminum zinc oxide (AZO), but the present disclosure is not limited thereto.

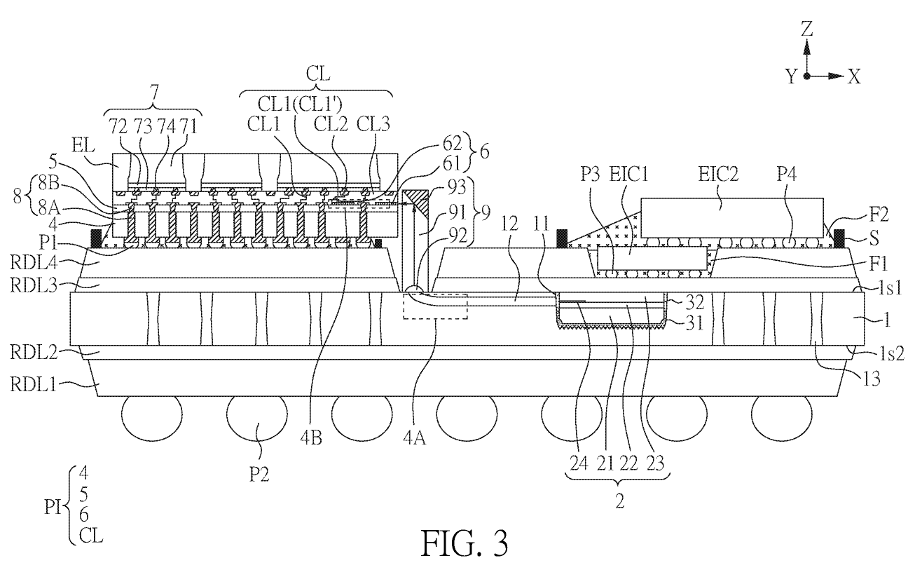

FIG. 3 is a cross-sectional schematic view of a part of an electronic device according to another embodiment of the present disclosure. The electronic device shown in FIG. 3 is similar to those shown in FIGS. 1A and 2A, except for the following differences.

In one embodiment of the present disclosure, as shown in FIG. 3, the electronic device comprises: a first substrate 1 comprising a cavity 11; a photonic die 2 disposed in the cavity 11 of the first substrate 1; a first waveguide 12 disposed corresponding to the photonic die 2 and receiving an optical signal from the photonic die 2; a second substrate 4 disposed on the first substrate 1; a semiconductor die 7 disposed on the second substrate 4; and a third waveguide 61 disposed between the second substrate 4 and the semiconductor die 7 and receiving the optical signal through the first waveguide 12.

In the present disclosure, the detail structures and features of the first substrate 1, the photonic die 2 and the first waveguide 12 may be referred to those disclosed in FIGS. 1A and 1B, and the detail structures and features of the second substrate 4, the semiconductor die 7 and the third waveguide 61 may be referred to those disclosed in FIGS. 2A and 2B, which are not described again here. In one embodiment of the present disclosure, the first substrate 1 is a glass substrate, and the second substrate 4 is a silicon substrate. In one embodiment of the present disclosure, for the light with wavelengths of 650 nm to 900 nm, the transmittance of the first substrate 1 may be greater than the transmittance of the second substrate 4. In one embodiment of the present disclosure, the refractive index of the third waveguide 61 may be greater than the refractive index of the first waveguide 12.

In one embodiment of the present disclosure, as shown in FIG. 3, the electronic device may further comprise a light transmission component 9 disposed on the first substrate 1 and used to transmit the optical signal from the first waveguide 12 to the third waveguide 61. That is, the optical signal provided by the photonic die 2 may be transmitted to the first waveguide 12 through the second waveguide 24, and then the optical signal is transmitted to the third waveguide 61 through the light transmission component 9. More specifically, the light transmission component 9 may comprise a light transmission medium 91, a lens 92 and a reflection unit 93, wherein the lens 92 may be used to concentrate the optical signal provided by the first waveguide 12 and transmit it to the reflection unit 93 through the light transmission medium 91, and the reflection unit 93 may reflect the optical signal to the third waveguide 61. In the present disclosure, the light transmission medium 91 may be a substance that can provide optical signal transmission, such as air, vacuum, optical fiber or other suitable substances. In the present disclosure, the lens 92 may be, for example, a convex lens, but the present disclosure is not limited thereto. In the present disclosure, the reflection unit 93 may be, for example, a reflector, but the present disclosure is not limited thereto.

In one embodiment of the present disclosure, as shown in FIG. 3, the electronic device may further comprise: a first redistribution layer RDL1; a second redistribution layer RDL2 disposed on the first redistribution layer RDL1, wherein the first substrate 1 is disposed on the second redistribution layer RDL2; a third redistribution layer RDL3 disposed on the first substrate 1; and a fourth redistribution layer RDL4 disposed on the third redistribution layer RDL3, wherein the second substrate 4 is disposed on the fourth redistribution layer RDL4. The circuit in the first redistribution layer RDL1 may be electrically connected to the circuit in the second redistribution layer RDL2, the circuit in the third redistribution layer RDL3 may be electrically connected to the circuit in the fourth redistribution layer RDL4, and the circuit in the second redistribution layer RDL2 may be electrically connected to the circuit in the third redistribution layer RDL3 through the conductive material disposed in the through hole 13 of the first substrate 1 to transmit signal from one side of the first substrate 1 to the other side thereof. In one embodiment of the present disclosure, the conductive unit 8 may be electrically connected to the circuit of the fourth redistribution layer RDL4 through the pad P1. In one embodiment of the present disclosure, the circuit in the first redistribution layer RDL1 may be electrically connected to a pad P2, thereby transmitting the signal to an external component (not shown in the figure). In the present disclosure, the first redistribution layer RDL1, the second redistribution layer RDL2, the third redistribution layer RDL3 and the fourth redistribution layer RDL4 may selectively have multiple layer design respectively, and may comprise a circuit structure formed by alternatively laminated conductive lines and insulating layers.

In one embodiment of the present disclosure, as shown in FIG. 3, the electronic device may further comprise: a first semiconductor die EIC1 disposed on the third redistribution layer RDL3, wherein the first semiconductor die EIC1 may be electrically connected to the photonic die 2 through the circuit of the third redistribution layer RDL3; and a second semiconductor die EIC2 disposed on the fourth redistribution layer RDL4, wherein the first semiconductor die EIC1 may be electrically connected to the second semiconductor die EIC2. More specifically, the first semiconductor die EIC1 may be, for example, electrically connected to the circuit of the third redistribution layer RDL3 through a pad P3, and the second semiconductor die EIC2 may be, for example, electrically connected to the first semiconductor die EIC1 through another pad P4. In the present disclosure, the first semiconductor die EIC1 and the second semiconductor die EIC2 may respectively comprise a system-on-chip (SoC), a central processing unit (CPU), a graphics processing unit (GPU), a memory, a logic die or a combination thereof, but the present disclosure is not limited thereto.

In the present disclosure, an electrical signal may be applied to the first semiconductor die EIC1 and/or the second semiconductor die EIC2, the electrical signal is transmitted to the photonic die 2 through the circuit of the third redistribution layer RDL3, the photonic die 2 convers the receiving electrical signal into corresponding optical signal, so the photonic die 2 can provide an optical signal. The optical signal is transmitted to the photoelectric converter 62 through the first waveguide 12, the light transmission component 9 and the third waveguide 61 in sequence, and the photoelectric converter 62 may convert the optical signal into another electrical signal to provide to the semiconductor die 7, thereby achieving signal transmission. Because optical signals have the advantages of fast transmission and low power loss, the electronic device of the present disclosure converts light into electrical signals through photonic die 2, thereby improving transmission efficiency and/or reducing transmission energy loss, thereby alleviating problems such as poor transmission efficiency and/or device overheating.

In one embodiment of the present disclosure, as shown in FIG. 3, the electronic device may further comprise: a filler F1 disposed on the third redistribution layer RDL3 and surrounding the first semiconductor die EIC1 , wherein the filler F1 may further be disposed in the gap between the first semiconductor die EIC1 and the third redistribution layer RDL3 to improve the reliability of the first semiconductor die EIC1 fixing on the third redistribution layer RDL3. Similarly, as shown in FIG. 3, the electronic device may further comprise: another filler F2 disposed on the fourth redistribution layer RDL4 and surrounding the second semiconductor die EIC2, the filler F2 may further be disposed in the gap between the second semiconductor die EIC2 and the fourth redistribution layer RDL4, to improve the reliability of the second semiconductor die EIC2 fixing on the fourth redistribution layer RDL4. In the present disclosure, the filler F1 and the filler F2 may respectively comprise a thermosetting resin, such as epoxy resins, but the present disclosure is not limited thereto.

In one embodiment of the present disclosure, as shown in FIG. 3, the electronic device may further comprise: a blocking structure S disposed on the fourth redistribution layer RDL4 and surrounding the filler F2, wherein the blocking structure S may be used to confine the disposition position of the filler F2. More specifically, the filler F2 may be applied in liquid or semi-liquid form on the fourth redistribution layer RDL4 and confined to the area formed by the blocking structure S. Through capillary action, the filler F2 fills the gap between the second semiconductor die EIC2 and the fourth redistribution layer RDL4. The filler F2 is then cured to fix the second semiconductor die EIC2 on the fourth redistribution layer RDL4. In the present disclosure, the material of the blocking structure S may comprise s ilicon oxide, silicon nitride, silicon oxynitride, resin, photoresist, other suitable materials, or combinations thereof, but the present disclosure is not limited thereto.

Hereinafter, other features of the first waveguide 12 and the third waveguide 61 are described below.

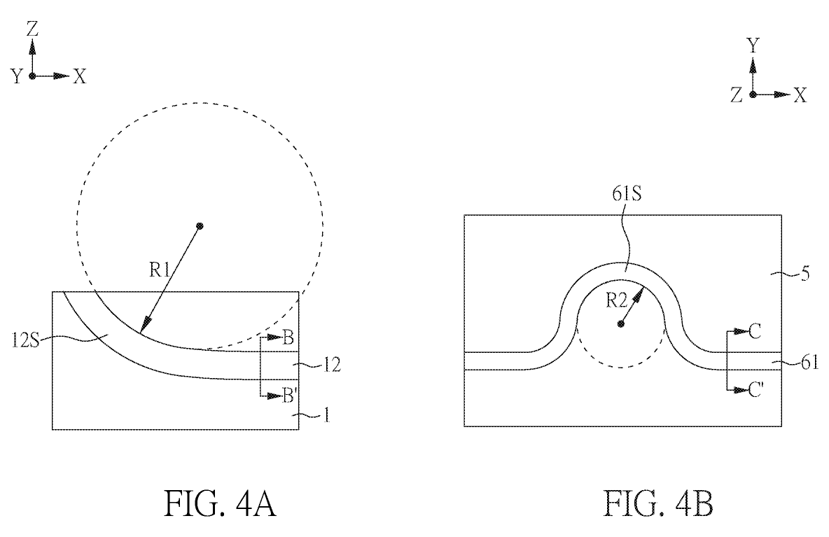

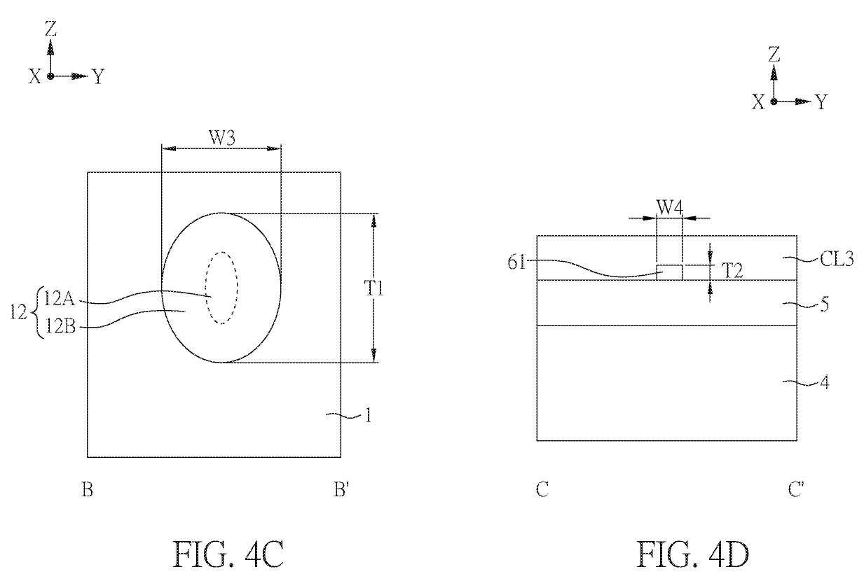

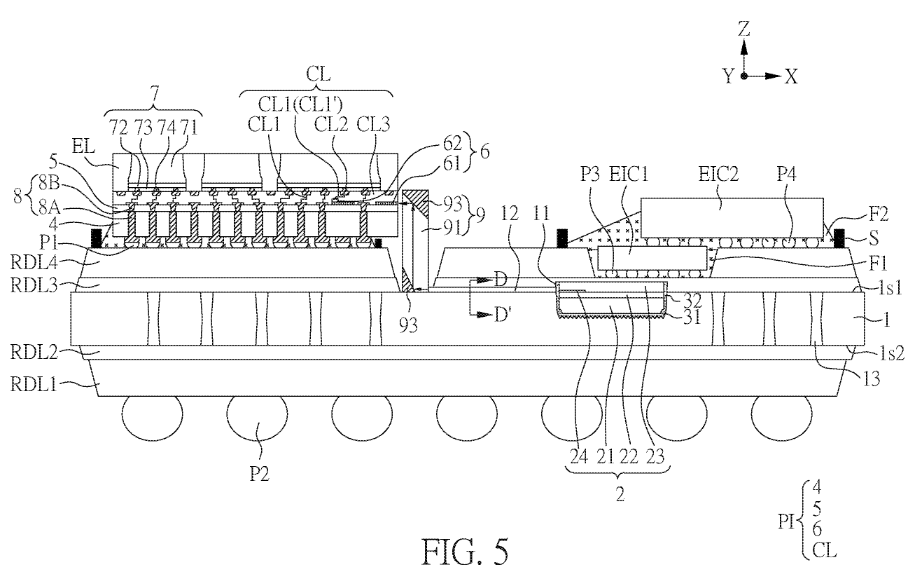

FIG. 4A is a cross-sectional schematic view of a part of a first waveguide according to one embodiment of the present disclosure. FIG. 4B is a top view of a part of a third waveguide according to one embodiment of the present disclosure. FIG. 4C is a cross-sectional schematic view of the line B-B’ in FIG. 4A. FIG. 4D is a cross-sectional schematic view of the line C-C’ in FIG. 4B. FIGS. 4A and 4B are partial enlarged views of FIG. 3. In addition, for the convenience of explanation, some components are omitted in the figure.

In one embodiment of the present disclosure, as shown in FIG. 4A and FIG. 4B, the first waveguide 12 comprises a first curve segment 12S, and the third waveguide 61 comprises a second curve segment 61S, wherein the first radius of curvature R1 of the first curve segment 12S is greater than the second radius of curvature R2 of the second curve segment 61S. In one embodiment of the present disclosure, the first curvature of the first curve segment 12S is less than the second curvature of the second curve segment 61S.

In one embodiment of the present disclosure, as shown in FIG. 4C and FIG. 4D, in a cross section, the first waveguide 12 has a first width W3 and a first thickness T1, and the third waveguide 61 has a second width W4 and a second thickness T2, wherein the first width W3 is greater than the second width W4, and the first thickness T1 is greater than the second thickness T2. In one embodiment of the present disclosure, a ratio of the second width W4 to the first width W3 may be greater than 0 and less than or equal to 0.5 (that is, 0 < W4/W3 ≤ 0.5), but the present disclosure is not limited thereto. The “width” refers to, for example, t he maximum lateral dimension of the component in the cross-sectional view. The “thickness” refers to, for example, the maximum dimension of the component along the normal direction Z of the substrate (for example, the first substrate 1 or the second substrate 4) in the cross-sectional view.

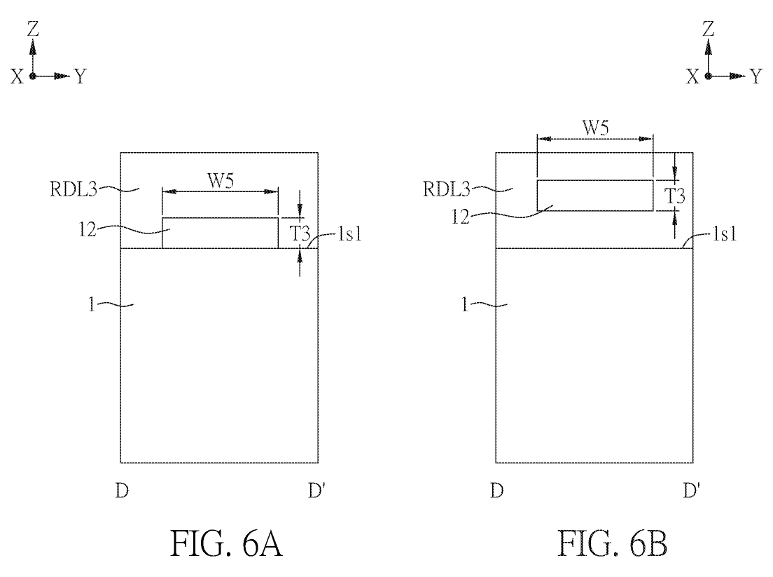

FIG. 5 is a cross-sectional schematic view of a part of an electronic device according to another embodiment of the present disclosure. FIGS. 6A and 6B respectively are cross-sectional schematic views of the line D-D’ in FIG. 5 according to different embodiments. Herein, the electronic device shown in FIG. 5 is similar to that shown in FIG. 3, except for the following differences.

In one embodiment of the present disclosure, as shown in FIG. 5, the first waveguide 12 of the electronic device may be disposed on the first substrate 1. More specifically, in one embodiment, as shown in FIG. 6A, the first waveguide 12 may be directly disposed on the first substrate 1, that is the first waveguide 12 may directly contact the upper surface 1s1 of the first substrate 1, and third redistribution layer RDL3 may be disposed on the first waveguide 12. In another embodiment, as shown in FIG. 6B, the first waveguide 12 may be disposed on the first substrate 1 and further in the third redistribution layer RDL3, that is, the first waveguide 12 does not directly contact the upper surface 1s1 of the first substrate 1, and conductive lines and/or insulating layers of the third redistribution layer RDL3 may be comprised between the first waveguide 12 and the upper surface 1s1 of the first substrate 1. In this embodiment, the width W5 of the first waveguide 12 may be greater than the second width W4 of the third waveguide 61 (as shown in FIG. 4D), and the thickness T3 of the first waveguide 12 may be greater than the second thickness T2 of the third waveguide 61 (as shown in FIG. 4D). In one embodiment of the present disclosure , the ratio of the second width W4 to the width W5 may be greater than 0 and less than or equal to 0.5 (that is, 0 < W4/W5 ≤ 0.5), but the present disclosure is not limited thereto.

In one embodiment of the present disclosure, as shown in FIG. 5, the light transmission component 9 may comprise a light transmission medium 91 and two reflection units 93, and the reflection units 93 transmit the optical signal to the third waveguide 61 by reflection. More specifically, the optical signal provided by the photonic die 2 may transmit to the first waveguide 12 through the second waveguide 24, and then the optical signal is transmitted to the third waveguide 61 through the light transmission component 9.

In the present disclosure, other features of the electronic device may be referred to that of FIG. 3, which are not described again here.

In the present disclosure, by disposing the photonic die and/or waveguide in the electronic device, the electronic device may be used to transmit optical signal, thereby improving electronic device problems such as poor transmission efficiency and/or device overheating.

The above specific embodiments should be construed as merely illustrative and not limiting in any way the remainder of the present disclosure.

1. An electronic device, comprising:
a first substrate comprising a cavity, wherein the cavity has a first bottom surface;
a photonic die disposed in the cavity and having a second bottom surface facing the first bottom surface;
a connection element disposed between the first bottom surface and the second bottom surface; and
a first waveguide disposed corresponding to the photonic die and configured to receive an optical signal from the photonic die,
wherein a roughness of the first bottom surface of the first substrate is different from a roughness of the second bottom surface of the photonic die.

2. The electronic device of claim 1, wherein the roughness of the first bottom surface of the first substrate is greater than the roughness of the second bottom surface of the photonic die.

3. The electronic device of claim 1, wherein the first waveguide is embedded in the first substrate.

4. The electronic device of claim 1, wherein a height from the connection element to the first bottom surface of the cavity is less than a height from the first waveguide to the first bottom surface of the cavity.

5. The electronic device of claim 1, wherein the photonic die further comprises a second waveguide used to transmit the optical signal to the first waveguide.

6. The electronic device of claim 5, further comprising an optical layer disposed between the first waveguide and the second waveguide.

7. The electronic device of claim 1, wherein the first waveguide is disposed on the first substrate.

8. The electronic device of claim 1, wherein the photonic die comprises a chamfer structure in a cross section.

9. An electronic device, comprising:
a second substrate comprising a first through hole and a first side surface surrounding the first through hole;
an insulating layer disposed on the second substrate and comprising a second through hole and a second side surface surrounding the second through hole, wherein the first through hole and the second through hole are overlapped in a top view direction of the electronic device;
an active layer disposed on the insulating layer and comprising a third waveguide and a photoelectric converter optically coupled to the third waveguide;
a semiconductor die disposed on the active layer and electrically connected to the photoelectric converter; and
a conductive unit electrically connected to the semiconductor die and comprising a first portion and a second portion, wherein the first portion is disposed in the first through hole, and the second portion is disposed in the second through hole,
wherein a roughness of the first side surface of the second substrate is different from a roughness of the second side surface of the insulating layer.

10. The electronic device of claim 9, wherein the roughness of the first side surface of the second substrate is greater than the roughness of the second side surface of the insulating layer.

11. The electronic device of claim 9, wherein a width of the second through hole of the insulating layer is less than a width of the first through hole of the second substrate in a cross section.

12. The electronic device of claim 9, wherein the third waveguide and the second through hole are not overlapped in a top view direction of the electronic device.

13. The electronic device of claim 9, wherein the insulating layer contacts the second substrate and the active layer.

14. An electronic device, comprising:
a first substrate comprising a cavity;
a photonic die disposed in the cavity of the first substrate;
a first waveguide disposed corresponding to the photonic die and receiving an optical signal from the photonic die;
a second substrate disposed on the first substrate;
a semiconductor die disposed on the second substrate; and
a third waveguide disposed between the second substrate and the semiconductor die and receiving the optical signal through the first waveguide.

15. The electronic device of claim 14, wherein a first width of the first waveguide is greater than a second width of the third waveguide.

16. The electronic device of claim 15, wherein a ratio of the second width to the first width is greater than 0 and less than or equal to 0.5.

17. The electronic device of claim 14, wherein a first thickness of the first waveguide is greater than a second thickness of the third waveguide.

18. The electronic device of claim 14, wherein the first waveguide comprises a first curve segment, the third waveguide comprises a second curve segment, and a first radius of curvature of the first curve segment is greater than a second radius of curvature of the second curve segment.

19. The electronic device of claim 14, wherein a transmittance of the first substrate is greater than a transmittance of the second substrate for light with wavelengths of 650 nm to 900 nm.

20. The electronic device of claim 14, wherein the first substrate is a glass substrate and the second substrate is a silicon substrate.
